(19) United States
(12) Patent Application Publication
(10) Pub. No.: US 2025/0246468 A1
(43) Pub. Date: Jul. 31, 2025

(54) SEMICONDUCTOR WAFER TRANSFER METHOD AND SEMICONDUCTOR WAFER TRANSFER DEVICE

(71) Applicant: Renesas Electronics Corporation, Tokyo (JP)

(72) Inventors: Kazuki NAKASHIMA, Tokyo (JP); Akimasa TANIGUCHI, Tokyo (JP)

(21) Appl. No.: 18/950,430

(22) Filed: Nov. 18, 2024

(30) Foreign Application Priority Data
Jan. 26, 2024 (JP) 2024-010173

(51) Int. Cl. H01L 21/68; H01L 21/683

(52) U.S. Cl. CPC H01L 21/681; H01L 21/6838

(57) ABSTRACT

The method for transporting the semiconductor wafer involves the steps of preparing the non-contact chuck provided with an optical sensor and the semiconductor wafer having a first main surface, positioning the non-contact chuck so that the optical sensor and the first main surface face each other with a predetermined interval therebetween, measuring a first intensity, which is the intensity of a reflected light from the first main surface, by illuminating the first main surface with a light from the optical sensor before bringing the non-contact chuck close to the first main surface, bringing the non-contact chuck close to the first main surface and maintaining the semiconductor wafer in a non-contact state by blowing gas to the first main surface from the non-contact chuck, and disengaging the non-contact chuck from the semiconductor wafer by moving the non-contact chuck away from the first main surface.

### CROSS-REFERENCE TO RELATED APPLICATIONS

The disclosure of Japanese Patent Application No. 2024-010173 filed on Jan. 26, 2024, including the specification, drawings and abstract is incorporated herein by reference in its entirety.

BACKGROUND

This disclosure relates to a method and device for transporting a semiconductor wafer.

For example, Japanese Patent Laid-Open No. 2023-97770 (Patent Document 1) discloses a semiconductor wafer transport device equipped with a non-contact chuck. The non-contact chuck holds the semiconductor wafer in a non-contact state by blowing gas to the main surface of the semiconductor wafer. A sensor is provided on the non-contact chuck facing the main surface of the semiconductor wafer to determine whether the semiconductor wafer is being held by the non-contact chuck.

### SUMMARY

A reflective sensor can be considered as a sensor provided on the non-contact chuck. The reflective sensor measures the of reflected light from a main surface of the intensity semiconductor wafer. Comparing this intensity with a preset threshold to determine whether the non-contact chuck has disengaged from the semiconductor wafer may lead to errors in judgment. Other objects and novel features will become apparent from the description of this specification and the accompanying drawings.

The method of transporting a semiconductor wafer according to this disclosure includes preparing a non-contact chuck provided with an optical sensor and the semiconductor wafer having a first main surface, arranging the non-contact chuck so that the optical sensor and the first main surface face each other across a gap, measuring a first intensity, which is the intensity of a reflected light from the first main surface, by the optical sensor before bringing the non-contact chuck close to the first main surface and illuminating the first main surface with the light, holding the semiconductor wafer in a non-contact state by the non-contact chuck blowing gas to the first main surface as the non-contact chuck is brought closer to the first main surface, disengaging the non-contact chuck from the semiconductor wafer by moving the non-contact chuck away from the first main surface, and measuring a second intensity, which is the intensity of a reflected light from the first main surface, by the optical sensor while moving the non-contact chuck away from the first main surface. The process of disengaging the non-contact chuck from the semiconductor wafer includes determining that the non-contact chuck has disengaged from the semiconductor wafer when the second intensity matches the first intensity. According to the method of transporting the semiconductor wafer of this disclosure, it is possible to suppress errors in determining whether the non-contact chuck has disengaged from the semiconductor wafer.

### BRIEF DESCRIPTION OF THE DRAWINGS

FIG. 1 is a schematic plan view of a semiconductor wafer transfer device DEV.

FIG. 2 is a schematic side view of the semiconductor wafer transfer device DEV.

FIG. 3 is a functional block diagram of the semiconductor wafer transfer device DEV.

FIG. 4 is a schematic plan view of the semiconductor wafer transfer device DEV according to a modified example.

FIG. 5 is a flow chart of a method for transporting a semiconductor wafer SW using the semiconductor wafer transfer device DEV.

FIG. 6 is a schematic side view explaining the chuck arranging step S2.

FIG. 7 is a schematic side view explaining the reflectance measurement step S3.

FIG. 8 is a schematic side view explaining the semiconductor wafer SW holding step S4.

FIG. 9 is a schematic side view explaining the semiconductor wafer detaching step S5.

FIG. 10 is a graph showing the intensity of a reflected light measured by an optical sensor OS when the distance between the optical sensor OS and a first main surface MS1 is changed.

FIG. 11 is a graph showing the relationship between the color on the surface of the semiconductor wafer SW and the reflectance of red light on the surface of the semiconductor wafer SW.

### DETAILED DESCRIPTION

Embodiment of this disclosure is described with reference to the drawings. In the following drawings, the same or corresponding parts are denoted by the same reference numerals, and redundant description will not be repeated. A semiconductor wafer conveying device related to the embodiment is referred to as a semiconductor wafer transfer device DEV.

### (Structure of Semiconductor Wafer Transfer Device DEV)

The structure of the semiconductor wafer transfer device DEV is explained below.

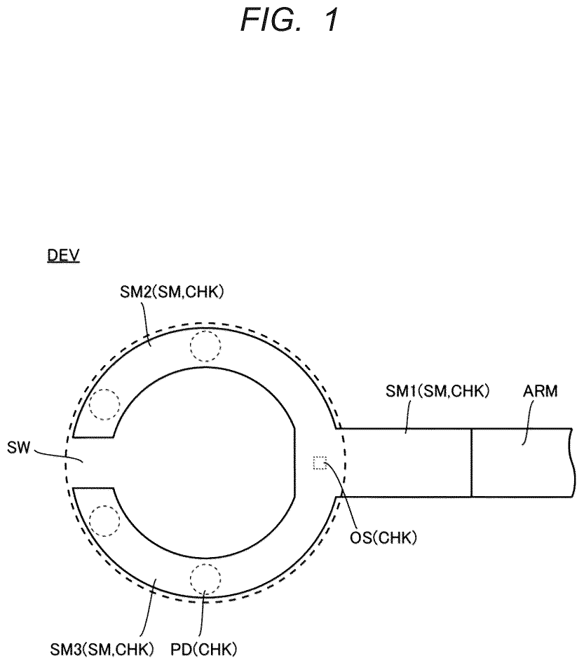

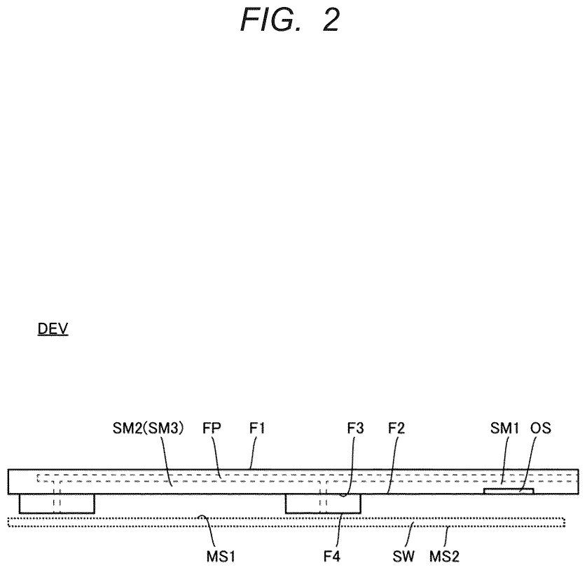

FIG. 1 is a schematic plan view of the semiconductor wafer transfer device DEV. FIG. 2 is a schematic side view of the semiconductor wafer transfer device DEV. As shown in FIGS. 1 and 2, the semiconductor wafer transfer device DEV has a non-contact chuck CHK. The non-contact chuck CHK holds a semiconductor wafer

SW without contact. The semiconductor wafer SW is shown in dashed lines in FIGS. 1 and 2. The semiconductor wafer SW has a first main surface MS1 and a second main surface MS2. The second main surface MS2 is the opposite surface of the first main surface MS1. The first main surface MS1 and the second main surface MS2 are end surfaces in a thickness direction of the semiconductor wafer SW.

The semiconductor wafer SW is, for example, a silicon wafer, a SOI (Silicon On Insulator) wafer, a silicon carbide wafer, a sapphire wafer, a gallium nitride wafer, a gallium phosphide wafer, or a gallium arsenide wafer. However, the semiconductor wafer SW is not limited to these. An electrical circuit pattern is formed on one of the first main surface MS1 and the second main surface MS2. For example, the electrical circuit pattern is formed on the first main surface MS1.

The non-contact chuck CHK has a support member SM, a plurality of pads PD, and an optical sensor OS. The support member SM has a first surface F1 and a second surface F2. The second surface F2 is the opposite surface of the first surface F1. The first surface F1 and the second surface F2 are end surfaces in the thickness direction of the support member SM. The support member SM has, for example, in plan view, i.e., when viewed from the first surface F1 side along the normal direction of the first surface F1, a first portion SM1, a second portion SM2, and a third portion SM3.

The first portion SM1 extends linearly in plan view. The semiconductor wafer transfer device DEV has a transfer arm ARM, and the non-contact chuck CHK is attached to the transfer arm ARM at the first portion SM1. The support member SM branches into the second portion SM2 and the third portion SM3 at the tip of the first portion SM1. The second portion SM2 and the third portion SM3 have shapes that fit an outer periphery of the first main surface MS1 in plan view. However, the tips of the second portion SM2 and the third portion SM3 are spaced apart from each other. From another perspective, the second portion SM2 and the third portion SM3 are horseshoe-shaped in plan view.

The plurality of pads PD are attached to the second surface F2. More specifically, the plurality of pads PD are attached to the second surface F2 of the second portion SM2 and the second surface F2 of the third portion SM3. The plurality of pads PD are, for example, circular in plan view. The plurality of pads PD have a third surface F3 and a fourth surface F4. The third surface F3 faces the second surface F2. The fourth surface F4 is the opposite surface of the third surface F3. The third surface

F3 and the fourth surface F4 are end surfaces in the thickness direction of the pad PD. Inside the support member SM and inside the pad PD, flow paths FP are formed. The flow paths FP are shown in dashed lines in FIG. 2.

Gas flowing through the flow paths FP is directed from a nozzle connected to the flow paths FP towards the first main surface MS1 from the fourth surface F4 and is discharged between the fourth surface F4 and the first main surface MS1. This creates a vacuum state between the fourth surface F4 and the first main surface MS1, allowing the non-contact chuck CHK to hold the semiconductor wafer SW in a non-contact state. For example, the non-contact chuck CHK is a Bernoulli chuck or a cyclone chuck. When the non-contact chuck CHK is the Bernoulli chuck, the gas is radially emitted from the nozzle, and when the non-contact chuck CHK is the cyclone chuck, the gas is emitted from the nozzle as a swirling flow.

The optical sensor OS, for example, is a reflective sensor. It has a light source and a light-receiving part. The optical sensor OS is installed on the non-contact chuck CHK so that its light source and the light-receiving part face the semiconductor wafer SW (first main surface MS1). More specifically, the optical sensor OS is located on the second surface F2 at the tip of the first portion SM1. From another perspective, the light source and light-receiving part of the optical sensor OS face a peripheral portion of the first main surface MS1.

The light source of the optical sensor OS illuminates the first main surface MS1 with a light L. For example, the light source is a red semiconductor laser. That is, a wavelength of the light L emitted by the light source of the optical sensor OS is, for example, 640 nm or more and 770 nm or less. The light-receiving part of the optical sensor OS outputs a signal corresponding to the intensity of the light L reflected by the first main surface MS1. The light source of the optical sensor OS may also be capable of emitting light L of multiple different wavelengths to the first main surface MS1.

The transfer arm ARM is moved along a horizontal direction (parallel to the first surface F1 or the second surface F2) by a driving mechanism not shown. Thus, the non-contact chuck CHK is also moved along the horizontal direction. Furthermore, the transfer arm ARM is moved along the vertical direction (normal to the first surface F1 or the second surface F2) by the aforementioned driving mechanism. Consequently, the non-contact chuck CHK is also moved in the vertical direction. The driving mechanism can tilt the non-contact chuck CHK by the operation of the transfer arm ARM so that the first surface F1 or the second surface F2 tilts relative to the horizontal direction. Tilting the non-contact chuck CHK also tilts the semiconductor wafer SW it holds, enabling the reading of markings or the like on the main surface of the semiconductor wafer SW.

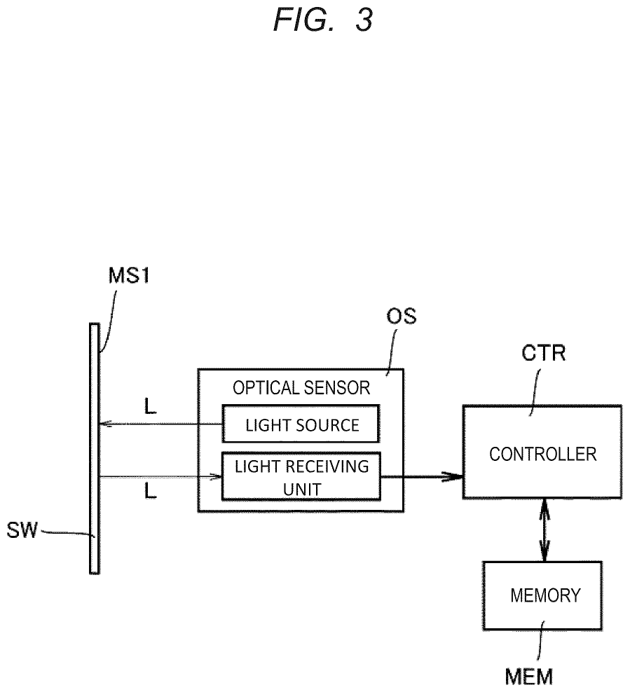

FIG. 3 is a functional block diagram of the semiconductor wafer transfer device DEV. As shown in FIG. 3, the semiconductor wafer transfer device DEV has a controller CTR and a memory MEM. The light-receiving part of the optical sensor OS is connected to the controller CTR, and an output signal from the light-receiving part of the optical sensor OS is inputted into the controller CTR. The memory MEM is connected to the controller

CTR. The controller CTR is composed of, for example, a microcontroller, and the memory MEM is composed of, for example, DRAM (Dynamic Random Access Memory), flash memory, etc.

### MODIFIED EXAMPLE

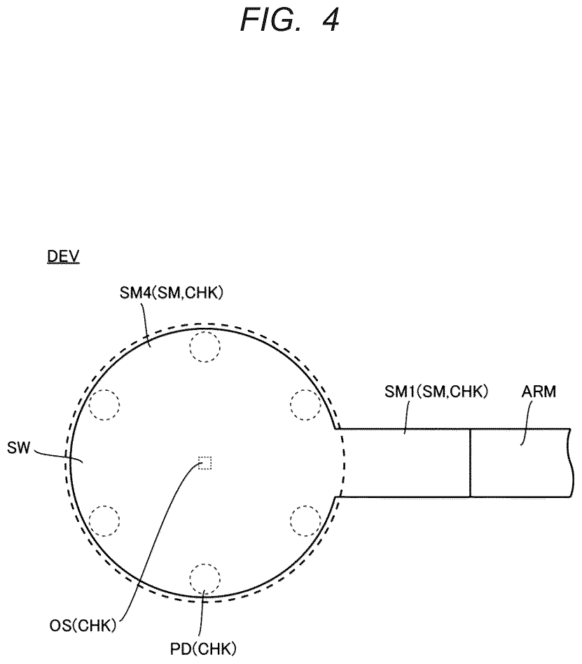

Although the example where the support member SM has a horseshoe shape in plan view has been described above, the plan shape of the support member SM is not limited to this. FIG. 4 is a schematic plan view of the semiconductor wafer transfer device DEV according to the modified example. As shown in FIG. 4, the support member SM may have a fourth portion SM4 instead of the second portion SM2 and the third portion SM3. The fourth portion SM4 may be circular in plan view.

In this case, the optical sensor OS may be arranged to face a central portion of the first main surface MS1. In the above, although the example where the object held by the non-contact chuck CHK is the semiconductor wafer SW has been described, the object held by the non-contact chuck CHK is not limited to the semiconductor wafer SW. The object held by the non-contact chuck CHK may be paper. More specifically, the object held by the non-contact chuck CHK may be an interlayer paper interposed between two adjacent semiconductor wafers SW when stacking a plurality of semiconductor wafers SW. A color of the interlayer paper may be different from a color of a surface of the semiconductor wafer SW.

### (Transporting Method Using Semiconductor Wafer Transfer Device DEV)

Below, the Transporting method of the semiconductor wafer SW using the semiconductor wafer transfer device DEV is described.

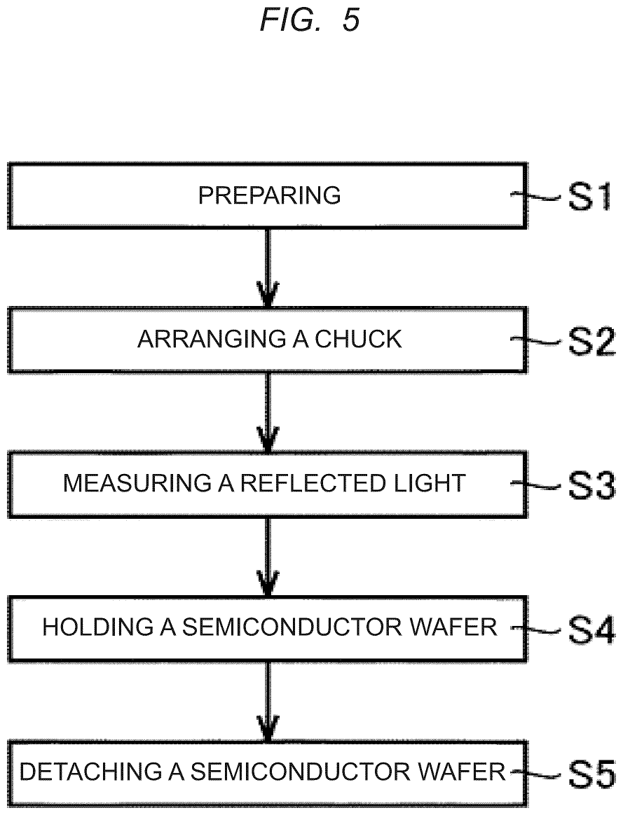

FIG. 5 is a flow chart of the transporting method of the semiconductor wafer SW using the semiconductor wafer transfer device DEV. As shown in FIG. 5, the transporting method of the semiconductor wafer SW using the semiconductor wafer transfer device DEV includes a preparation step S1, a chuck arranging step S2, a reflected light measurement step S3, a semiconductor wafer holding step S4, and a semiconductor wafer detaching step S5.

In the preparation step S1, the semiconductor wafer transfer device DEV and the semiconductor wafer SW are prepared. After the preparation step S1, the chuck arranging step S2 is performed.

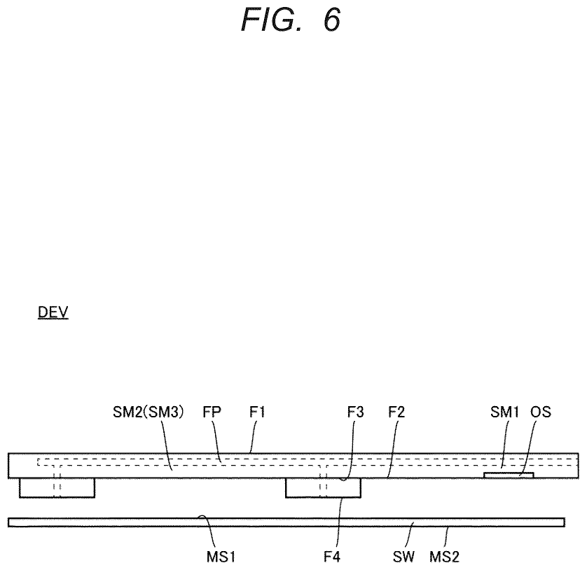

FIG. 6 is a schematic side view explaining the chuck arranging step S2. As shown in FIG. 6, in the chuck arranging step S2, the non-contact chuck CHK is moved over the semiconductor wafer SW so that the second surface F2 faces the first main surface MS1 with a predetermined interval therebetween. After the chuck arranging step S2, the reflected light measurement step S3 is performed.

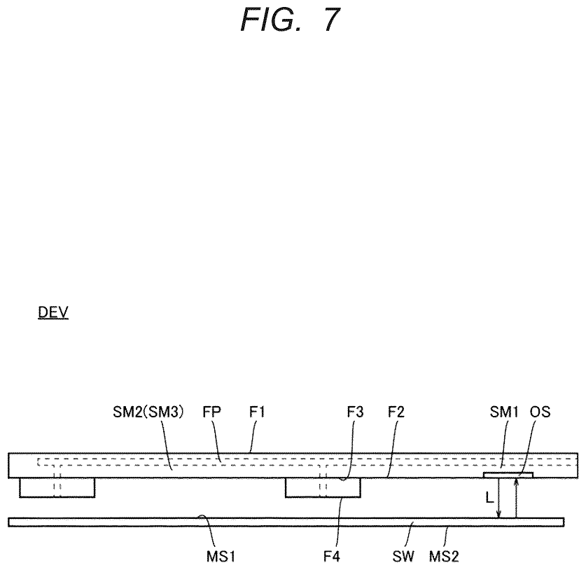

FIG. 7 is a schematic side view explaining the reflected light measurement step S3. As shown in FIG. 7, in the reflected light measurement step S3, the light source of the optical sensor OS irradiates a light L to the first main surface MS1. The light L is reflected by the first main surface MS1 and then enters the light-receiving part of the optical sensor OS. The light-receiving part of the optical sensor OS outputs a signal corresponding to the intensity of the light L that entered to the controller CTR. The controller CTR stores the intensity of the light L in the memory MEM. After the reflected light measurement step S3 is performed, the semiconductor wafer holding step S4 is performed.

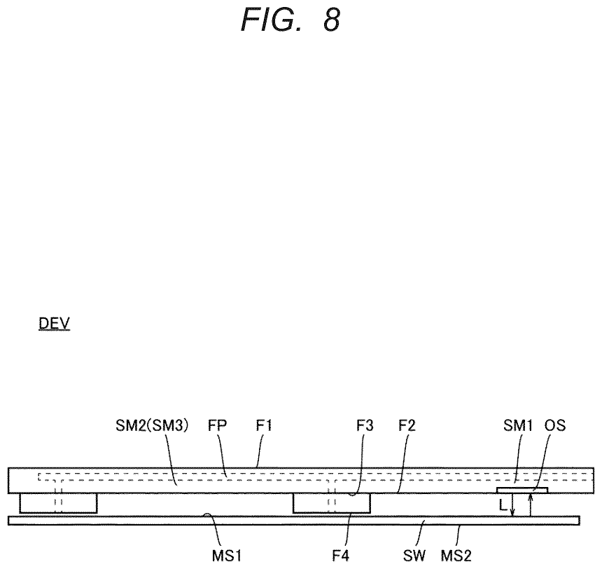

FIG. 8 is a schematic side view explaining the semiconductor wafer holding step S4. As shown in FIG. 8, in the semiconductor wafer holding step S4, the non-contact chuck CHK is brought closer to the first main surface MS1. As a result, a vacuum state is formed due to the gas being blown from the nozzle of the fourth surface F4 to the first main surface MS1, and the semiconductor wafer SW is held in the non-contact state by the non-contact chuck CHK.

During the process of the non-contact chuck CHK approaching the first main surface MS1, the light source of the optical sensor OS irradiates a light L to the first main surface MS1, and the light-receiving part of the optical sensor OS outputs a signal corresponding to the intensity of the light L reflected by the first main surface MS1 to the controller CTR. The controller CTR compares the intensity of the light L being measured in this process with the intensity of the light L stored in the memory MEM during the reflected light measurement step S3, and determines that the non-contact chuck CHK has held the semiconductor wafer SW if the former intensity is less than the latter. After the semiconductor wafer holding step S4, a semiconductor wafer detaching step S5 is performed.

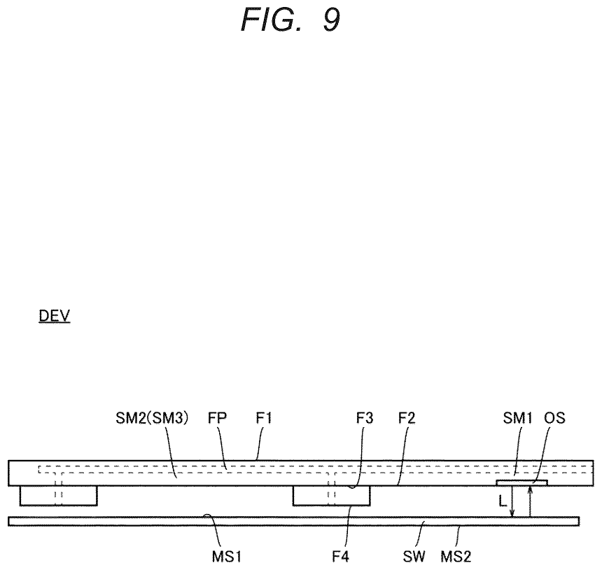

FIG. 9 is a schematic side view explaining the semiconductor wafer detaching step S5. As shown in FIG. 9, in the semiconductor wafer detaching step S5, the non-contact chuck CHK is separated from the first main surface MS1. As a result, the attractive force from the non-contact chuck CHK no longer reaches the semiconductor wafer SW, allowing the non-contact chuck CHK to detach from the semiconductor wafer SW.

During the process of the non-contact chuck CHK moving away from the first main surface MS1, the light source of the optical sensor OS illuminates the first main surface MS1 with a light L, and the light-receiving part of the optical sensor OS outputs to the controller CTR a signal corresponding to the intensity of the light L reflected from the first main surface MS1. The controller CTR compares the intensity of the light L being measured in this process with the intensity of the light L stored in the memory MEM during the reflected light measurement step S3, and determines that the non-contact chuck CHK has detached from the semiconductor wafer SW when the former and latter intensities match.

### (Effect of the Semiconductor Wafer Transfer Device DEV)

The effect of the semiconductor wafer transfer device DEV will be described below in comparison with a comparative example.

To hold the semiconductor wafer SW, a contact chuck, more specifically, a vacuum chuck may be used. With a vacuum chuck, it is possible to determine whether the chuck has detached from the semiconductor wafer SW or not based on changes in the suction pressure. However, while a vacuum chuck can be applied to hold the semiconductor wafer SW by suctioning the second main surface MS2, it cannot be applied to hold the semiconductor wafer SW by suctioning the first main surface MS1 where the electrical circuit pattern is formed.

Therefore, to hold the semiconductor wafer SW on the first main surface MS1, it is necessary to use the non-contact chuck CHK such as the Bernoulli chuck or the cyclone chuck. When determining whether the non-contact chuck CHK is holding the semiconductor wafer SW (or whether the non-contact chuck CHK has detached from the semiconductor wafer SW) using the reflective sensor provided in the non-contact chuck CHK, a threshold is set in advance, and the determination is made by comparing this threshold with the intensity of the reflected light on the first main surface MS1.

However, in this case, the state of light reflection on the first main surface MS1 changes due to the warping of the semiconductor wafer SW, a type of the semiconductor wafer SW on the first main surface MS1, the state of the electrical circuit pattern formation, etc. As a result, it is difficult to accurately determine whether the non-contact chuck CHK is holding the semiconductor wafer SW (or whether the non-contact chuck CHK has detached from the semiconductor wafer SW) by the method described above.

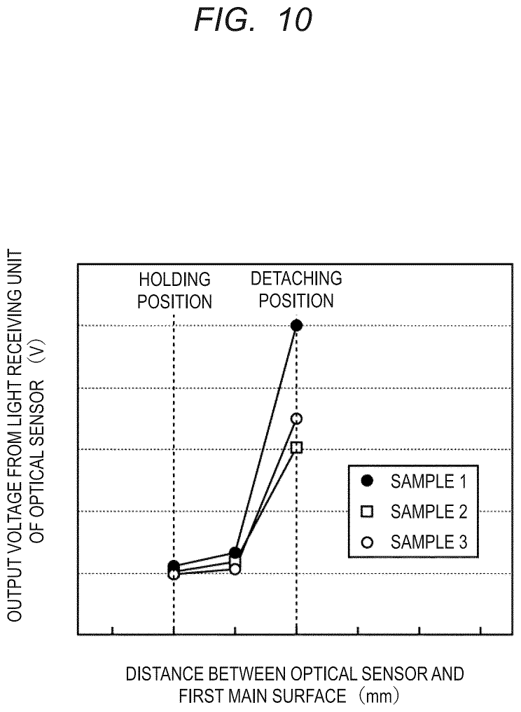

FIG. 10 is a graph showing the intensity of the reflected light measured by the light-receiving part of the optical sensor OS when the distance between the optical sensor OS and the first main surface MS1 is changed. In Samples 1 and 2 of FIG. 10, the semiconductor wafer SW is a silicon wafer. In Sample 3 of FIG. 10, the semiconductor wafer SW is a silicon carbide wafer. In Sample 1 of FIG. 10, an electrical circuit pattern is formed on the first main surface MS1, while in Samples 2 and 3 of FIG. 10, no electrical circuit pattern is formed on the first main surface MS1. The vertical axis of FIG. 10 represents the voltage of the output signal from the light-receiving part of the optical sensor OS, and the horizontal axis of FIG. 10 represents the distance between the optical sensor OS and the first main surface MS1.

As shown in FIG. 10, when comparing Sample 1 with Sample 2, that is, comparing cases with and without the electrical circuit pattern formed on the first main surface MS1, the output from the light-receiving part of the optical sensor OS differs for each sample when the non-contact chuck CHK is holding the semiconductor wafer SW, and also differs for each sample when the non-contact chuck CHK is disengaged from the semiconductor wafer SW. Furthermore, when comparing Sample 2 with Sample 3, that is, when the type of the semiconductor wafer SW differs, the output from the light-receiving part of the optical sensor OS differs for each sample when the non-contact chuck CHK is holding the semiconductor wafer SW, and also differs for each sample when the non-contact chuck CHK is disengaged from the semiconductor wafer SW.

However, in all samples, it is common that the output from the light-receiving part of the optical sensor OS changes whether the non-contact chuck CHK is holding the semiconductor wafer SW or is disengaged from it.

The semiconductor wafer transfer device DEV focuses on the change in the output from the light-receiving part of the optical sensor OS when the non-contact chuck CHK is holding the semiconductor wafer SW and when it is disengaged. If the intensity of a light L measured as the non-contact chuck CHK moves away from the first main surface MS1 matches the intensity of a light L stored in the memory MEM during the reflected light measurement step S3, it is determined that the non-contact chuck CHK is disengaged from the semiconductor wafer SW.

Similarly, from the same perspective, the semiconductor wafer transfer device DEV determines that the non-contact chuck CHK is holding the semiconductor wafer SW if the intensity of the light L measured as the non-contact chuck CHK approaches the first main surface MS1 becomes less than the intensity of the light L stored in the memory MEM during the reflected light measurement step S3. Therefore, according to the semiconductor wafer transfer device DEV, even if the type of the semiconductor wafer SW or the state of formation of the electrical circuit pattern differs, it is possible to suppress errors in determining whether the non-contact chuck CHK is holding the semiconductor wafer SW (or is disengaged from it).

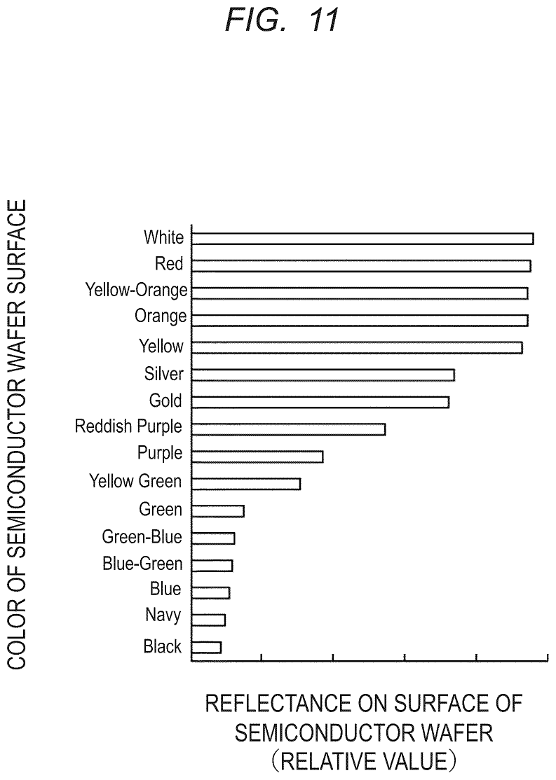

FIG. 11 is a graph showing the relationship between the color of the surface of the semiconductor wafer SW and the reflectance of red light on the surface of the semiconductor wafer SW. As shown in FIG. 11, the reflectance of red light on the surface of the semiconductor wafer SW varies significantly depending on the color of the surface. Therefore, attempting to determine whether the non-contact chuck CHK is holding the semiconductor wafer SW (or if the non-contact chuck CHK has disengaged from the semiconductor wafer SW) by comparing the preset threshold with the output from the light-receiving part of the reflective sensor may lead to incorrect determination results.

On the other hand, the fact that the output from the light-receiving part of the optical sensor OS changes whether the non-contact chuck CHK is holding the semiconductor wafer SW or has disengaged from the semiconductor wafer SW is common regardless of the color of the surface of the semiconductor wafer SW. Therefore, according to the semiconductor wafer transfer device DEV, even if the color of the surface of the semiconductor wafer SW is different, it is possible to suppress errors in determining whether the non-contact chuck CHK is holding the semiconductor wafer SW (or if the non-contact chuck CHK has disengaged from the semiconductor wafer SW).

In one case, multiple semiconductor wafers SW are stacked with the interlayer paper in between and placed in a case, and these multiple semiconductor wafers SW and the interlayer paper may be sequentially transported to a different case. Since the color of the surface of the semiconductor wafer SW and the color of the interlayer paper are different from each other, in this case, objects of different colors will be alternately held and released by the non-contact chuck CHK. As mentioned above, in the semiconductor wafer transfer device DEV, even if the colors of the objects to be transported differ, it is less likely to make errors in determining whether the non-contact chuck CHK is holding the object (or if the non-contact chuck CHK has disengaged from the object), making it possible to perform such transport without replacing the non-contact chuck CHK.

As described above, although the invention made by the present inventors has been described in detail based on the embodiments, it is needless to say that the present invention is not limited to the above-described embodiments and can be variously modified without departing from the gist thereof.

What is claimed is:

1. A method of transporting a semiconductor wafer comprising the steps of:
(a) preparing a non-contact chuck provided with an optical sensor and the semiconductor wafer having a first main surface;
(b) arranging the non-contact chuck such that the optical sensor and the first main surface face each other with a predetermined interval therebetween
(c) before moving the non-contact chuck closer to the first main surface, radiating a light by the optical sensor to the first main surface and measuring a reflected light with a first intensity reflected from the first main surface;
(d) moving the non-contact chuck close to the first main surface and holding the semiconductor wafer in a non-contact state by blowing gas to the first main surface from the non-contact chuck;
(e) detaching the semiconductor wafer from the non-contact chuck by moving the non-contact chuck away from the first main surface; and
(f) during a process of moving the non-contact chuck away from the first main surface, radiating a light by the optical sensor to the first main surface and measuring a reflected light with a second intensity reflected from the first main surface, wherein
in the step of (f), when the second intensity becomes the first intensity, it is determined that the semiconductor wafer has been detached.

2. The method of transporting the semiconductor wafer according to claim 1, wherein
the non-contact chuck is a Bernoulli chuck or a cyclone chuck.

3. The method of transporting the semiconductor wafer according to claim 1, wherein
the non-contact chuck is disposed such that the optical sensor faces a central portion of the first main surface.

4. The method of transporting the semiconductor wafer according to claim 1, wherein
the non-contact chuck is disposed such that the optical sensor faces a peripheral portion of the first main surface.

5. The method of transporting the semiconductor wafer according to claim 1, wherein
the optical sensor is a reflective sensor.

6. The method of transporting the semiconductor wafer according to claim 1, wherein
the optical sensor has a light source for irradiating a light to the first main surface, and the light source is a red semiconductor laser.

7. The method of transporting the semiconductor wafer according to claim 6, wherein
a wavelength of the light source is 640 nm or more and 770 nm or less.

8. The method of transporting the semiconductor wafer according to claim 1, wherein
the semiconductor wafer is selected from a group consisting of a silicon wafer, an SOI wafer, a silicon carbide wafer, a sapphire wafer, a gallium nitride wafer, a gallium phosphide wafer, and a gallium arsenide wafer.

9. The method of transporting the semiconductor wafer according to claim 1, wherein
an electrical circuit pattern is formed on either the first main surface or a second main surface opposite to the first main surface of the semiconductor wafer.

10. The method of transporting the semiconductor wafer according to claim 9, wherein
the electrical circuit pattern is formed on the first main surface.

11. The method of transporting the semiconductor wafer according to claim 1, further comprising:
(d1) in the step of (d), during a process of moving the non-contact chuck close to the first main surface, radiating a light by the optical sensor to the first main surface and measuring a reflected light with a third intensity reflected
in the step of (d1), when the third intensity becomes smaller than the first intensity, it is determined that the semiconductor wafer has been held.

12. A semiconductor wafer transfer device comprising:
a non-contact chuck provided with an optical sensor disposed to face the first main surface of the semiconductor wafer, wherein
the non-contact chuck holds the semiconductor wafer in a non-contact state by blowing gas to the first main surface from the non-contact chuck and the semiconductor wafer by moving the non-contact chuck away from the first main surface,
before moving the non-contact chuck closer to the first main surface, the optical sensor radiates a light to the first main surface and measures a reflected light with a first intensity reflected from the first main surface,
in a process of moving the non-contact chuck away from the first main surface, radiates a light by the optical sensor to the first main surface and measures a reflected light with a second intensity reflected from the first main surface,
in a case of the second intensity and the first intensity are same, it is determined that the semiconductor wafer has been detached.

13. The semiconductor wafer transfer device according to claim 12, wherein
the non-contact chuck is a Bernoulli chuck or a cyclone chuck.

14. The semiconductor wafer transfer device according to claim 12, wherein
the non-contact chuck is disposed such that the optical sensor faces a central portion of the first main surface.

15. The semiconductor wafer transfer device according to claim 12, wherein
the non-contact chuck is disposed such that the optical sensor faces a peripheral portion of the first main surface.

16. The semiconductor wafer transfer device according to claim 12, wherein
the optical sensor is a reflective sensor.

17. The semiconductor wafer transfer device according to claim 12, wherein
the optical sensor has a light source for irradiating a light to the first main surface, and the light source is a red semiconductor laser.

18. The semiconductor wafer transfer device according to claim 17, wherein
a wavelength of the light source is 640 nm or more and 770 nm or less.

19. The semiconductor wafer transfer device according to claim 12, wherein
in a process of moving the non-contact chuck close to the first main surface, the optical sensor radiates a light to the first main surface and measures a reflected light with a third intensity reflected from the first main surface,
in a case of the third intensity is smaller than the first intensity, it is determined that the semiconductor wafer has been held.
